(19) United States
(12) Patent Application Publication
(10) Pub. No.: US 2023/0391955 A1
(43) Pub. Date: Dec. 7, 2023

(54) POLYIMIDE PRECURSOR, POLYIMIDE, AND FLEXIBLE PRINTED CIRCUIT BOARD

(71) Applicant: SHOWA DENKO MATERIALS CO. LTD., Tokyo (JP)

(72) Inventors: Tomoaki MAENO, Chiyoda-ku, Tokyo (JP); Yasunori KAWABATA, Chiyoda-ku, Tokyo (JP)

(21) Appl. No.: 18/035,607

(22) PCT Filed: Nov. 11, 2021
(86) PCT No.: PCT/JP2021/041200

§ 371 Date: May 5, 2023

(30) Foreign Application Priority Data
Nov. 10, 2020 (WO) PCT/JP2020/041929

(51) Int. Cl. C08G 73/10; H05K 1/03

(52) U.S. Cl. CPC C08G 73/105; H05K 1/0346; H05K 1/0393; H05K 2201/0154

(57) ABSTRACT

Provided are a polyimide precursor which contains a diamine-derived structural unit and a tetracarboxylic dianhydride-derived structural unit, contains a dimer diamine-derived structural unit in an amount of at least 10 mol % but not more than 80 mol % relative to total units of the diamine-derived structural unit, has a weight average molecular weight of at least 15,000 but not more than 130,000, and is used for a base film of a flexible printed circuit board, as well as a resin composition containing the polyimide precursor, and a polyimide obtained using the resin composition.

### TECHNICAL FIELD

Embodiments of the present invention relate to a polyimide precursor, a resin composition, a polyimide, a polyimide molded article, and a flexible printed circuit board (FPC).

### BACKGROUND ART

Polyimides exhibit excellent heat resistance, have good mechanical strength, and also display superior chemical resistance, and are consequently used in a variety of applications. Further, because polyimides also exhibit superior insulation properties, they are also used as insulation materials in electronic components and machinery components. As a result of having these types of characteristics, polyimides are used as substrates and coating films such as protective films for displays, solar cells, touch panels, organic EL lighting, and millimeter-wave radar and the like.

In recent years, as a result of demands for further miniaturization and weight reduction, higher levels of integration and higher frequencies are being sought for electronic components, and further improvements are required in the dielectric characteristics of insulating materials across a wide frequency range, including high frequencies. Insulation properties can be obtained by lowering the dielectric constant of a material, but in order to reduce transmission signal loss, lowering the dielectric loss tangent is also important. Because transmission loss becomes more problematic in the high-frequency region, reduction of the dielectric loss tangent in the high-frequency region is desirable.

Patent Document 1 proposes a solvent-insoluble polyimide film containing more than 15 mol % but less than 50 mol % of a dimer diamine relative to the total diamine component as a polyimide film that has a low dielectric constant and a low dielectric loss tangent, and exhibits insolubility in solvents.

Patent Document 2 proposes a solvent-insoluble polyimide film containing at least 5 mol % but not more than 25 mol % of a dimer diamine relative to the total diamine component as a polyimide film that has a low dielectric constant and a low coefficient of thermal expansion, and exhibits excellent rigidity and toughness.

### PRIOR ART DOCUMENTS

### Patent Documents

Patent Document 1: JP 2020-76072 A
Patent Document 2: JP 2020-7549 A

### SUMMARY OF THE INVENTION

### Problems to be Solved by the Invention

In Patent Document 1, the dielectric characteristics improve as the blend proportion of the dimer diamine is increased, but because the polyimide becomes more soluble in solvent, the upper limit for the blend proportion of the dimer diamine is restricted in order to obtain a polyimide film with appropriate solvent insolubility. Moreover, from the viewpoint of achieving a low coefficient of thermal expansion, Patent Document 1 proposes a laminate in which the polyimide containing the dimer diamine is sandwiched between a polyimide of low coefficient of thermal expansion containing no dimer diamine.

Patent Document 2 discloses that in order to achieve suitable rigidity and toughness, the elongation of the polyimide film is preferably at least 50% but not more than 90%. Polyimide films of excellent rigidity offer the advantage of having superior coating film formability, meaning they can readily form coating films on curved shapes, as the coating resin for electric wiring or the like.

On the other hand, in the conventional technology, when a dimer diamine is used to improve the dielectric characteristics, the strength of the resulting polyimide film is not entirely satisfactory. In this type of polyimide film, achieving a low dielectric constant and low dielectric loss tangent while also enhancing the strength is difficult, and in particular, achieving a satisfactory breaking elongation is problematic.

An object of the present disclosure is to provide a polyimide having excellent dielectric characteristics and breaking elongation, and a polyimide precursor used in obtaining the polyimide.

### Means to Solve the Problems

Some aspects of the present disclosure are as follows.
[1] A polyimide precursor which contains a diamine-derived structural unit and a tetracarboxylic dianhydride-derived structural unit, contains a dimer diamine-derived structural unit in an amount of at least 10 mol % but not more than 80 mol % relative to total units of the diamine-derived structural unit, has a weight average molecular weight of at least 15,000 but not more than 130,000, and is used for a base film of a flexible printed circuit board.
[2] A polyimide precursor which contains a diamine-derived structural unit and a tetracarboxylic dianhydride-derived structural unit, contains a dimer diamine-derived structural unit in an amount of at least 10 mol % but less than 50 mol % relative to total units of the diamine-derived structural unit, and has a weight average molecular weight exceeding 50,000 but not more than 130,000.
[3] A resin composition containing the polyimide precursor according to [1] or [2].
[4] A polyimide obtained using the polyimide precursor according to [1] or [2].
[5] A polyimide which contains a diamine-derived structural unit and a tetracarboxylic dianhydride-derived structural unit, contains a dimer diamine-derived structural unit in an amount of at least 5 mol % but not more than 80 mol % relative to total units of the diamine-derived structural unit, has a breaking elongation of at least 95%, and is used for a base film of a high-frequency flexible printed circuit board.
[6] A polyimide which contains a diamine-derived structural unit and a tetracarboxylic dianhydride-derived structural unit, contains a dimer diamine-derived structural unit in an amount of at least 5 mol % but not more than 80 mol % relative to total units of the diamine-derived structural unit, has a breaking elongation of at least 95% and a glass transition temperature of at least 200° C., and is used for a base film of a flexible printed circuit board.
[7] A polyimide which contains a diamine-derived structural unit and a tetracarboxylic dianhydride-derived structural unit, contains a dimer diamine-derived structural unit in an amount of at least 10 mol % but less than 50 mol % relative to total units of the diamine-derived structural unit, and has a breaking elongation of at least 95% and a glass transition temperature of at least 200° C.
[8] The polyimide according to any one of [4] to [7], wherein the dielectric constant Dk (10 GHz) is not more than 3.3.
[9] The polyimide according to any one of [4] to [8], wherein the dielectric loss tangent Df (10 GHz) is not more than 0.003.
[10] The polyimide according to any one of [4] to [9], wherein the glass transition temperature is at least 300° C.
[11] A polyimide molded article containing the polyimide according to any one of [4] to [10].
[12] A flexible printed circuit board containing the polyimide according to any one of [4] to [10].
[13] A flexible printed circuit board containing a base film obtained using the polyimide according to any one of [4] to [10].
[14] A flexible printed circuit board containing a base film and a coating film layer formed on the base film, wherein at least the coating film layer is obtained using the polyimide according to any one of [4] to [10].
[15] The flexible printed circuit board according to any one of [12] to [14], which is used for a millimeter-wave radar, a high-frequency antenna or a substrate for high-speed transmission.

### Effects of the Invention

According to one embodiment, a polyimide having excellent dielectric characteristics and breaking elongation, and a polyimide precursor used for obtaining this polyimide may be provided.

### EMBODIMENTS FOR CARRYING OUT THE INVENTION

One embodiment of the present invention is described below, but the present invention is not limited to the following examples.

### (Polyimide Precursor)

A polyimide precursor according to one embodiment of the present disclosure is obtained using a diamine and a tetracarboxylic dianhydride, wherein the polyimide precursor contains from 5 to 80 mol % of a dimer diamine relative to the total diamine component contained in the polyimide precursor, and has a weight average molecular weight within a range from 15,000 to 130,000.

One preferred example is a polyimide precursor which contains a diamine-derived structural unit and a tetracarboxylic dianhydride-derived structural unit, contains a dimer diamine-derived structural unit in an amount of at least 10 mol % but not more than 80 mol % relative to total units of the diamine-derived structural unit, has a weight average molecular weight of at least 15,000 but not more than 130,000, and is used for a base film of a flexible printed circuit board.

Another preferred example is a polyimide precursor which contains a diamine-derived structural unit and a tetracarboxylic dianhydride-derived structural unit, contains a dimer diamine-derived structural unit in an amount of at least 10 mol % but less than 50 mol % relative to total units of the diamine-derived structural unit, and has a weight average molecular weight exceeding 50,000 but not more than 130,000.

By using these exemplified polyimide precursors, a polyimide having excellent dielectric characteristics and breaking elongation can be provided. These polyimides can be used as polyimide molded articles in a wide variety of applications, and are suited to applications that require superior insulation properties.

It is thought that because the polyimides formed using these polyimide precursors include a dimer diamine skeleton, a reduction in the dielectric constant can be achieved as a result of an increase in the free volume. Further, in these polyimides, it is thought that as a result of the introduction of long-chain structures derived from the dimer diamine, the concentration of imide groups is lowered and the level of polar groups is reduced in a relative manner, enabling a lower dielectric loss tangent to be obtained.

Polyimides having a low dielectric constant can be used widely as insulation materials. In order to reduce transmission loss, ensuring a low dielectric loss tangent as well as a low dielectric constant is desirable. Because transmission loss tends to increase at higher frequencies, ensuring a low dielectric loss tangent even in the high-frequency region is desirable. A polyimide obtained using the polyimide precursor according to one embodiment is able to achieve a low dielectric constant and a low dielectric loss tangent, and those tendencies are displayed even in the high-frequency region. This type of polyimide can be used in all manner of electronic components and machinery components, and for example, can be used in displays, solar cells, touch panels, organic EL lighting, millimeter-wave radar, high-frequency antennas, and boards for high-speed transmission and the like. Among these applications, this type of polyimide can be used particularly favorably in devices used in the high-frequency region, and specific examples include millimeter-wave radar, high-frequency antennas, and boards for high-speed transmission. Millimeter-wave radar refers to radar that emits millimeter-waves toward a target object and then detects the target object by receiving the reflected waves from the target object, and millimeter-wave radar devices installed in vehicles and the like are used in collision prevention systems and automated driving systems and the like. In the case of high-frequency antennas, high frequencies and high-speed transmission are required in communication devices in order to achieve higher speed transmission, and in cases where the high-frequency antenna needs to be housed inside a casing in a small-scale communication device or the like, a material having a low dielectric constant and a low dielectric loss tangent is desirable. Examples of boards for high-speed transmission include high-speed transmission cables and high-speed transmission connectors and the like.

In the polyimide precursor of one embodiment, because the weight average molecular weight is large, the breaking elongation of the resulting polyimide is high, and the polyimide can be molded for use in a variety of applications such as a film-like form, a plate-like form and a molded article-like form. This polyimide can be used, for example, in a flexible printed circuit board. Because this polyimide has a high breaking elongation, even a single layer of the polyimide can be used as the base film of a flexible printed circuit board. Further, when this polyimide is formed in a film-like form on a substrate, because the resulting film has a high breaking elongation, damage to the film during bending of the substrate on which the film has been formed can be prevented. For example, the polyimide can be used in the flexible printed circuit boards of displays, solar cells, touch panels, organic EL lighting, millimeter-wave radar, high-frequency antennas and flexible printed circuit boards, such as boards for high-speed transmission, and particularly as the base film of flexible printed circuit boards. Among these applications, from the viewpoints of satisfying demands for low dielectric constant and low dielectric loss tangent characteristics in the high-frequency region, and also satisfying the demands for devices of reduced size and reduced thickness, the polyimide can be used specifically in the high-frequency flexible printed circuit boards of millimeter-wave radar, high-frequency antennas and boards for high-speed transmission and the like, and can be used particularly favorably for the base film of these high-frequency flexible printed circuit boards. High-frequency flexible printed circuit board are circuit boards that can be used, for example, in a high-frequency region of at least I GHz, at least 5 GHz, or at least 10 GHz. Further, the high-frequency flexible printed circuit board for use in millimeter-wave radar can preferably be used in a high-frequency region from 30 to 300 GHz.

The polyimide precursor of one embodiment has a weight average molecular weight within a range from 15,000 to 130,000, and therefore the chemical resistance and water resistance of the resulting polyimide can be improved. Polyimides are also materials that exhibit excellent heat resistance. For example, even in applications in high-temperature environments that involve contact with chemicals or water, this polyimide is resistant to degradation or the like caused by hydrolysis, and exhibits excellent dielectric characteristics. These types of characteristics are useful in components used in high-temperature environments, such as electronic components installed in the vicinity of vehicle engines For example, this polyimide is also useful in applications where transmission loss in the high-frequency region is problematic, such as vehicle-mounted millimeter-wave radar devices. Because the polyimide also has flexibility, by using the polyimide in the boards, protective film or combination thereof in a vehicle-mounted millimeter-wave radar, not only can excellent dielectric characteristics be achieved, but, when installing, the shape of the substrate can be changed to conform with the shape of the vehicle.

The polyimide precursor according to one embodiment can be obtained by synthesizing a polyamic acid using a diamine compound and a tetracarboxylic dianhydride compound. This synthesis can be conducted by mixing and polymerizing the diamine compound and the tetracarboxylic dianhydride compound in an organic solvent.

The polyimide precursor may include a dimer diamine as a diamine component.

Dimer diamines are compounds derived from dimer acids, and more specifically, are compounds derived from dimer acids that are dimers of an unsaturated fatty acid such as oleic acid or linoleic acid. Dimer diamines are, for example, compounds represented by general formulas (1) to (4) shown below. One of these dimer diamines may be used alone, or a combination of two or more such compounds may be used.

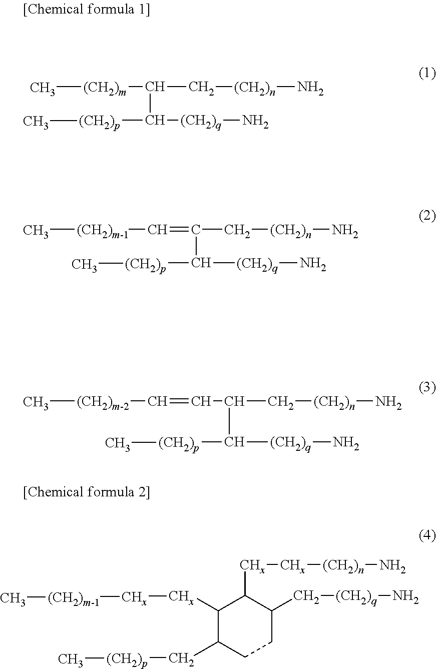

In the above general formulas (1) to (4), m, n, p and q are integers that satisfy m+n=6 to 17, and p+q=8 to 19. In general formula (4), each of the dashed lines indicates either a single bond or a double bond, and all of the dashed lines may be single bonds, or one or more or all of the dashed lines may be double bonds. In general formula (4), x is 2 in those cases where the dashed line between the CH, groups is a single bond, and is 1 when the dashed line is a double bond.

The dimer diamine is preferably a compound having a carbon ring structure, and is more preferably a compound represented by general formula (4). In the compound represented by general formula (4), it is preferable that the dashed line in the carbon ring structure is a single bond, that both of the dashed lines in the carbon chains are single bonds, or that some combination of these conditions applies, and it is particularly preferable that all of the dashed lines are single bonds. In general formula (4) it is preferable that m+n=10 to 12, p+q=10 to 12, or that a combination of these conditions applies.

Examples of commercially available products of dimer diamines include PRIAMINE 1075 and PRIAMINE 1074 (both brand names) and the like, manufactured by Croda Japan K.K.

The polyimide precursor according to one embodiment may contain from 5 to 80 mol % of the dimer diamine relative to the total diamine component contained in the polyimide precursor.

From the viewpoint of lowering the dielectric constant and the dielectric loss tangent of the resulting polyimide, the proportion of the dimer diamine relative to the total diamine component contained in the polyimide precursor is preferably at least 5 mol %, more preferably at least 10 mol %, even more preferably at least 20 mol %, and still more preferably 25 mol % or greater.

From the viewpoints of the heat resistance, tensile strength and tensile modulus of elasticity of the resulting polyimide, the proportion of the dimer diamine relative to the diamine component contained in the polyimide precursor is preferably not more than 80 mol %, more preferably 50 mol % or less than 50 mol %, even more preferably not more than 45 mol %, and still more preferably 40 mol % or less. From the viewpoints of obtaining superior heat resistance, and a high tensile strength or high tensile modulus of elasticity, this proportion of the dimer diamine is preferably not more than 40 mol %, more preferably not more than 35 mol %, and even more preferably 30 mol % or less.

For example, relative to the total diamine component contained in the polyimide precursor, the proportion of the dimer diamine is preferably within a range from 5 to 80 mol %, and more preferably from 10 to 80 mol %. The proportion may be within a range from 10 to 50 mol % or at least 10 mol % but less than 50 mol %. The proportion may also be within a range from 20 to 40 mol %. The proportion may also be within a range from 20 to 30 mol %. Within this ranges, the dielectric constant and the dielectric loss tangent can be lowered while maintaining various other characteristics.

Here, the amount of the dimer diamine relative to the diamine component contained in the polyimide precursor can be determined from the following formula, using the molar ratio of the diamine compound introduced into the reaction system.

((Number of moles of dimer diamine)/(total number of moles of diamine compound))×100 (mol %)

The polyimide precursor may include one or more other diamines besides the dimer diamine as part of the diamine component of the polyimide precursor.

Examples of this other diamine include aromatic diamines, alicyclic diamines, aliphatic diamines, and combinations of two or more types of these compounds. By including an aromatic diamine as a diamine component, any deterioration in the heat resistance can be better prevented.

In the aromatic diamine, the aromatic ring may be monocyclic or polycyclic. The polycyclic structure may contain two rings, three rings, or four rings or the like, or may be a condensed ring structure. The aromatic ring may be an aromatic hydrocarbon ring or an aromatic heterocycle. The aromatic diamine preferably contains a monocyclic structure such as a benzene ring, or a bicyclic structure such as a biphenyl, diphenylmethane or diphenyl ether structure. Further, the aromatic diamine may contain a substituent such as a nitrogen atom-containing group, a fluorine atom, a sulfonyl group, a sulfo group, or an alkyl group or the like.

Examples of the aromatic diamine include 4,4′-diaminodiphenylmethane, 3,3′-diaminodiphenylmethane, 3,4′-diaminodiphenylmethane, 4,4′-diamino-3,3′-dimethyldiphenylmethane, 4,4′-diaminodiphenylethane, 4,4′-diaminodiphenyl ether, 4,3′-diaminodiphenyl ether, 4,4′-diaminobiphenyl, 3,3′-diaminobiphenyl, 3,4′-diaminobiphenyl, 4,4′-diamino-3,3′-dimethylbiphenyl, 4,4′-diamino-2,2′-dimethylbiphenyl, 4,4′-diamino-3,3′-diethylbiphenyl, 4,4′-diamino-2,2′-diethylbiphenyl, 4,4′-diamino-3,3′-dimethoxybiphenyl, 4,4′-diamino-2,2′-dimethoxybiphenyl, 1,5-diaminonaphthalene, 2,6-diaminonaphthalene, 3-aminobenzylamine, 4-aminobenzylamine, tolylenediamine, m-xylylenediamine, p-xylylenediamine, 4,4′-bis(4-aminophenoxy)biphenyl, and 2,2-bis[4-(4-aminophenoxy)phenyl]propane.

Among these compounds, diamines having from 2 rings to 4 rings are preferred, and diamines having two benzene rings are more preferred. From another perspective, diamines having a phenyl ether structure are preferred. Specifically, 4,4′-diaminodiphenyl ether, 4,3′-diaminodiphenyl ether, 4,4′-bis(4-aminophenoxy)biphenyl, and combinations of these compounds are preferred, and 4,4′-diaminodiphenyl ether is more preferred.

In the alicyclic diamine, the alicyclic structure may be a cycloalkane, a cycloalkene or a cycloalkyne, and may be either a monocyclic structure, or a polycyclic structure with two rings, three rings, or four rings or the like.

In the alicyclic diamine, the number of carbon atoms in the alicyclic structure is preferably within a range from 3 to 20, more preferably from 4 to 12, and even more preferably from 6 to 10. This alicyclic structure is preferably a cycloalkane, and specific examples include cycloalkanes such as cyclopropane, cyclobutane, cyclopentane, cyclohexane, cycloheptane, cyclooctane, cyclooctane, cyclononane, cyclodecane, cycloundecane, cyclododecane and norbornane, as well as polycyclic structures having two or more of these cycloalkanes. Further, the alicyclic diamine may contain a substituent such as a nitrogen atom-containing group, a fluorine atom, a sulfonyl group, a sulfo group, or an alkyl group or the like.

Examples of the alicyclic diamine include 4,4′-methylenebis(cyclohexanamine), 4,4′-methylenebis(2-methylcyclohexanamine), 1,3-bis(aminomethyl)cyclohexane, 1,4-bis(aminomethyl)cyclohexane, 1,3-cyclohexanediamine, 1,4-cyclohexanediamine, isophoronediamine, norbornanediamine, bis(aminomethyl)norbornane, and hydrogenated m-xylylenediamine.

Examples of the aliphatic diamine include aliphatic diamines having a saturated or unsaturated hydrocarbon group and having from 4 to 20 carbon atoms, and preferably from 6 to 10 carbon atoms, per molecule, and specific examples include hexamethylenediamine and 2,2,4-trimethylhexamethylenediamine.

One type of the other diamines described above may be used, or a combination of two or more types may be used.

By using a combination of two or more types of diamine compound, the fluidity of a resin composition containing the polyimide precursor can be improved, enabling improved coatability. It is thought that this is because by mixing the two types of diamine compound, the production of by-products such as dissolution-resistant salts can be suppressed within the resin composition.

Examples of the tetracarboxylic dianhydride component of the polyimide precursor include aromatic tetracarboxylic dianhydrides, alicyclic tetracarboxylic dianhydrides, aliphatic tetracarboxylic dianhydrides, and combinations of two or more types of these compounds. By including an aromatic tetracarboxylic dianhydride as a tetracarboxylic dianhydride component, any deterioration in the heat resistance can be better prevented.

In the aromatic tetracarboxylic dianhydride, the aromatic ring may be monocyclic or polycyclic. The polycyclic structure may contain two rings, three rings, or four rings or the like, or may be a condensed ring structure. The aromatic ring may be an aromatic hydrocarbon ring or an aromatic heterocycle. The aromatic tetracarboxylic dianhydride preferably contains a monocyclic structure such as a benzene ring, or a bicyclic structure such as a biphenyl, diphenylmethane or diphenyl ether structure. Further, the aromatic tetracarboxylic dianhydride may contain a substituent such as a nitrogen atom-containing group, a fluorine atom, a sulfonyl group, a sulfo group, or an alkyl group or the like.

Examples of the aromatic tetracarboxylic dianhydride include pyromellitic dianhydride, 3,3′,4,4′-biphenyltetracarboxylic dianhydride, 2,3,3′,4′-biphenyltetracarboxylic dianhydride, 3,3′,4,4′-benzophenonetetracarboxylic dianhydride, 4,4′-oxydiphthalic anhydride, 3,4′-oxydiphthalic anhydride, 4,4′-sulfonyldiphthalic dianhydride, 1,2,5,6-naphthalenetetracarboxylic dianhydride, 1,4,5,8-naphthalenetetracarboxylic dianhydride, 2,3,5,6-perylenetetracarboxylic dianhydride, 3,4,9,10-perylenetetracarboxylic dianhydride, m-terphenyl-3,3′,4,4′-tetracarboxylic dianhydride, 2,2-bis(2,3- or 3,4-dicarboxyphenyl)propane dianhydride, 2,2-bis[4-(2,3- or 3,4-dicarboxyphenoxy)phenyl]propane dianhydride, 1,1,1,3,3,3-hexafluoro-2,2-bis(2,3- or 3,4-dicarboxyphenyl)propane dianhydride, 1,1,1,3,3,3-hexafluoro-2,2-bis[4-(2,3- or 3,4-dicarboxyphenoxy)phenyl]propane dianhydride, and 1,3-bis(3,4-dicarboxyphenyl)-1,1,3,3-tetramethyldisiloxane dianhydride.

Among these compounds, tetracarboxylic dianhydrides having one or two benzene rings are preferred, and for example, pyromellitic dianhydride, 3,3′,4,4′-biphenyltetracarboxylic dianhydride, or a combination thereof is preferred. Among these, tetracarboxylic dianhydrides having one benzene ring are preferred, and for example, pyromellitic dianhydride is preferred. In this case, the tetracarboxylic dianhydride having one benzene ring may represent at least 30 mol % of the total tetracarboxylic dianhydride component, is preferably at least 50 mol %, and may be from 80 to 100 mol %. Tetracarboxylic dianhydrides having one or two benzene rings, and more preferably one benzene ring, have a high imide concentration that contributes to intermolecular orientation, and can therefore further increase the glass transition temperature.

In the alicyclic tetracarboxylic dianhydride, the alicyclic structure may be a cycloalkane, a cycloalkene or a cycloalkyne, and may be either a monocyclic structure, or a polycyclic structure with two rings, three rings, or four rings or the like.

In the alicyclic tetracarboxylic dianhydride, the number of carbon atoms in the alicyclic structure is preferably within a range from 3 to 20, more preferably from 4 to 12, and even more preferably from 6 to 10. Examples of this alicyclic structure include cycloalkanes such as cyclopropane, cyclobutane, cyclopentane, cyclohexane, cycloheptane, cyclooctane, cyclooctane, cyclononane, cyclodecane, cycloundecane and cyclododecane, as well as polycyclic structures having two or more of these cycloalkanes. Further, the alicyclic tetracarboxylic dianhydride may contain a substituent such as a nitrogen atom-containing group, a fluorine atom, a sulfonyl group, a sulfo group, or an alkyl group or the like.

Examples of the alicyclic tetracarboxylic dianhydride include 1,2,4,5-cyclohexanetetracarboxylic dianhydride, 1,2,3,4-cyclopentanetetracarboxylic dianhydride, 1,2,3,4-cyclobutanetetracarboxylic dianhydride, 1,2,3,4-tetramethyl-1,2,3,4-cyclobutanetetracarboxylic dianhydride, bicyclo[2.2.2]-oct-7-ene-2,3,5,6-tetracarboxylic dianhydride, and 5-(2,5-dioxotetrahydrofuranyl)-3-methyl-3-cyclohexene-1,2-dicarboxylic dianhydride.

Examples of the aliphatic tetracarboxylic dianhydride include aliphatic tetracarboxylic dianhydrides having a saturated or unsaturated hydrocarbon group and having from 4 to 20 carbon atoms, and preferably from 6 to 10 carbon atoms, per molecule, and specific examples include butanetetracarboxylic dianhydride and the like.

One type of the tetracarboxylic dianhydrides described above may be used, or a combination of two or more types may be used.

In one embodiment, the weight average molecular weight of the polyimide precursor is preferably within a range from 15,000 to 130,000. The weight average molecular weight of the polyimide precursor is more preferably 50,000, or greater than 50,000 but not more than 130,000.

From the viewpoints of the breaking elongation, heat resistance, tensile strength and tensile modulus of elasticity of the resulting polyimide, and particularly from the viewpoint of the breaking elongation, the weight average molecular weight of the polyimide precursor is preferably at least 15,000, more preferably at least 30,000, even more preferably 50,000, or greater than 50,000, and still more preferably 60,000 or greater. Further, within these ranges, the film formability can also be improved when the polyimide precursor is used as a coating material. From the viewpoints of the breaking elongation, heat resistance, tensile strength and tensile modulus of elasticity of the resulting polyimide, the weight average molecular weight of the polyimide precursor may be at least 65,000, at least 70,000, at least 75,000, or 80,000 or greater.

From the viewpoint of suppressing increases in viscosity, the weight average molecular weight of the polyimide precursor is preferably not more than 130,000, and more preferably 100.000 or less. In applications which require reduced viscosity, the weight average molecular weight may be 90,000 or less, or even 80,000 or less. By suppressing any increase in viscosity, the film formability can be improved when the polyimide precursor is used as a coating material.

In one embodiment, the number average molecular weight of the polyimide precursor is preferably within a range from 10,000 to 80.000.

From the viewpoints of the breaking elongation, heat resistance, tensile strength and tensile modulus of elasticity of the resulting polyimide, and particularly from the viewpoints of the breaking elongation and the film formability upon use as a coating material, the number average molecular weight is preferably at least 10,000, more preferably at least 20,000, even more preferably at least 30,000, and still more preferably 40,000 or greater.

From the viewpoint of suppressing increases in viscosity, the number average molecular weight of the polyimide precursor is preferably not more than 80,000, more preferably not more than 60,000, even more preferably not more than 55,000, and still more preferably 50,000 or less. By suppressing any increase in viscosity, the film formability can be further improved upon use as a coating material.

In the present disclosure, weight average molecular weight (Mw) and number average molecular weight (Mn) values for resins indicate values measured by gel permeation chromatography (GPC) and then referenced against a calibration curve of standard polystyrenes. The calibration curve is approximated as a cubic equation using a 5-sample set of standard polystyrenes (TSK Standard POLYSTYRENE [brand name, manufactured by Tosoh Corporation]). The GPC conditions are shown below.
GPC apparatus: high-speed GPC apparatus HLC-8320GPC (brand name, manufactured by Tosoh Corporation)
Detector: ultraviolet absorption detector UV-8320 (brand name, manufactured by Tosoh Corporation)
Columns: Gelpack GL-S300MDT-5 (total: 2 columns) (brand name, manufactured by Show Denko Materials Co., Ltd.).
Eluent: THF/DMF=1/1 (volumetric ratio)+LiBr (0.06 mol/L)+H₃PO₄ (0.06 mol/L)
Flow rate: 1 ml/minute
Column size: 8 mm I.D.×300 mm
Sample concentration: 5 mg/I mL
Injection volume: 5 μL
Measurement temperature: 40° C.

One example of the polyimide precursor includes 5 to 20 mol % of the dimer diamine relative to the total diamine component contained in the polyimide precursor, and has a weight average molecular weight of 60,000 or greater. The polyimide obtained using the polyimide precursor of this example has a high breaking elongation, and has a dielectric constant of not more than 3.3 or a dielectric loss tangent of not more than 0.005, or is capable of satisfying both of these conditions.

Another example of the polyimide precursor includes 10 to 20 mol % of the dimer diamine relative to the total diamine component contained in the polyimide precursor, and has a weight average molecular weight of 60,000 or greater. The polyimide obtained using the polyimide precursor of this example has a high breaking elongation, and has a dielectric constant of not more than 3.0 or a dielectric loss tangent of not more than 0.003, or is capable of satisfying both of these conditions.

Yet another example of the polyimide precursor includes at least 20 mol % and either 50 mol % or less than 50 mol % of the dimer diamine relative to the total diamine component contained in the polyimide precursor, and has a weight average molecular weight of 60,000 or greater. The polyimide obtained using the polyimide precursor of this example has a high breaking elongation, and has a dielectric constant of not more than 2.9 or a dielectric loss tangent of not more than 0.0015, or is capable of satisfying both of these conditions.

Yet another example of the polyimide precursor includes at least 20 mol % and either 30 mol % or less than 30 mol % of the dimer diamine relative to the total diamine component contained in the polyimide precursor, and has a weight average molecular weight of 60,000 or greater. The polyimide obtained using the polyimide precursor of this example has a high breaking elongation, and has a dielectric constant of not more than 2.9 or a dielectric loss tangent of not more than 0.0015, or is capable of satisfying both of these conditions.

Yet another example of the polyimide precursor includes from 20 mol % to 80 mol % of the dimer diamine relative to the total diamine component contained in the polyimide precursor, and has a weight average molecular weight of 60,000 or greater. The polyimide obtained using the polyimide precursor of this example has a high breaking elongation, and has a dielectric constant of not more than 2.9 or a dielectric loss tangent of not more than 0.0015, or is capable of satisfying both of these conditions.

Yet another example of the polyimide precursor includes from 30 mol % to 80 mol % of the dimer diamine relative to the total diamine component contained in the polyimide precursor, and has a weight average molecular weight of 60.000 or greater. The polyimide obtained using the polyimide precursor of this example has a high breaking elongation, and has a dielectric constant of not more than 2.7 or a dielectric loss tangent of not more than 0.0015, or is capable of satisfying both of these conditions.

Yet another example of the polyimide precursor includes from 50 mol % to 80 mol % of the dimer diamine relative to the total diamine component contained in the polyimide precursor, and has a weight average molecular weight of 60.000 or greater. The polyimide obtained using the polyimide precursor of this example has a high breaking elongation, and has a dielectric constant of not more than 2.7 or a dielectric loss tangent of not more than 0.0015, or is capable of satisfying both of these conditions.

The polyimide precursor according to one embodiment need only satisfy one of the compositions described above, and there are no particular limitations on the production method used. One example of a method for producing the polyimide precursor is described below, but the polyimide precursor according to one embodiment is not limited to polyimide precursors produced using the following production method.

One example of a method for producing the polyimide precursor may include reacting a diamine compound and a tetracarboxylic dianhydride compound.

The diamine compound may include a dimer diamine. In addition to the dimer diamine, the diamine compound may also include one or more other diamines such as an aromatic diamine, alicyclic diamine or aliphatic diamine.

The tetracarboxylic dianhydride compound may include an aromatic tetracarboxylic dianhydride, an alicyclic tetracarboxylic dianhydride, or an aliphatic tetracarboxylic dianhydride or the like.

Details regarding the diamine compound and the tetracarboxylic dianhydride compound are as described above.

The mixing ratio between the diamine compound and the tetracarboxylic dianhydride compound, expressed as a molar ratio, may be, for example, approximately 1:1, or may be adjusted within a range from 1.00:0.95 to 1.00:1.05.

The reaction between the diamine compound and the tetracarboxylic dianhydride may be conducted as a solution polymerization.

Examples of the synthesis solvent include polar solvents such as N-methyl-2-pyrrolidone, N,N′-dimethylformamide, γ-butyrolactone, N,N-dimethylpropylene urea [1,3-dimethyl-3,4,5,6-tetrahydropyrimidin-2(1H)-one], dimethyl sulfoxide, diethylene glycol dimethyl ether, triethylene glycol dimethyl ether, sulfolane and dimethylacetamide, aromatic hydrocarbon solvents such as xylene and toluene, and ketones such as methyl ethyl ketone and methyl isobutyl ketone. Either one type of solvent, or a combination of two or more types of solvent, may be used.

The amount of the synthesis solvent used during the reaction is preferably within a range from 100 to 600 parts by mass, and more preferably from 200 to 400 parts by mass, per 100 parts by mass for the combined mass of the diamine and the tetracarboxylic dianhydride. By ensuring that the amount used of the synthesis solvent is at least 100 parts by mass, the various components can be reacted uniformly. By ensuring that the amount used of the synthesis solvent is not more than 600 parts by mass, the polymerization reaction can be accelerated. Further, using a relatively small amount of the synthesis solvent enables the resin concentration of the resulting resin composition to be increased, which means a thicker coating film can be achieved when used as a coating material.

A polyimide precursor synthesized using the above method is able to exhibit a weight average molecular weight within the range described above. For example, the weight average molecular weight can be adjusted by sampling the polyimide precursor during the synthesis, and then continuing the synthesis until the target weight average molecular weight is reached. The number average molecular weight of the polyimide precursor can be controlled in a similar manner to the weight average molecular weight.

There are no particular limitations on the reaction temperature, and any temperature that enables the raw materials to be mixed within the synthesis solvent and allows the reaction to proceed is suitable, and for example, the temperature may be not more than 50° C. or 40° C. or lower, and may be at least 10° C. or 20° C. or higher. From the viewpoint of obtaining a polyimide precursor with a high molecular weight, the reaction time is preferably at least 3 hours, more preferably at least 5 hours, and even more preferably 8 hours or longer. The reaction end point may be determined by sampling the reaction product and measuring the weight average molecular weight, and then continuing the reaction until the target weight average molecular weight is reached.

The polyimide precursor described above can be used to provide a polyimide. This polyimide has a low dielectric constant and low dielectric loss tangent, and can therefore be used favorably for an insulating polyimide molded article. Because this polyimide is obtained by a dehydration cyclization of the high-molecular weight polyimide precursor, a polyimide molded article having excellent breaking elongation, heat resistance, tensile strength and tensile modulus of elasticity, and in particular a polyimide molded article of superior breaking elongation, can be provided. This type of polyimide molded article is useful in all manner of applications that require favorable dielectric characteristics and breaking elongation, and for example, is useful for application to flexible printed circuit boards.

### (Resin Composition)

A resin composition according to one embodiment of the present disclosure is characterized as including the polyimide precursor according to one of the embodiments described above.

One preferred example is a resin composition in which the polyimide precursor is obtained using a diamine and a tetracarboxylic dianhydride, contains from 5 to 80 mol % of a dimer diamine relative to the total diamine component contained in the polyimide precursor, and has a weight average molecular weight within a range from 15,000 to 130,000.

Another preferred example is a resin composition used for a base film of a flexible printed circuit board, containing a polyimide precursor which contains a diamine-derived structural unit and a tetracarboxylic dianhydride-derived structural unit, contains a dimer diamine-derived structural unit in an amount of at least 10 mol % but not more than 80 mol % relative to total units of the diamine-derived structural unit, and has a weight average molecular weight of at least 15,000 but not more than 130,000.

Yet another preferred example is a resin composition containing a polyimide precursor in which the polyimide precursor contains a diamine-derived structural unit and a tetracarboxylic dianhydride-derived structural unit, contains a dimer diamine-derived structural unit in an amount of at least 10 mol % but less than 50 mol % relative to total units of the diamine-derived structural unit, and has a weight average molecular weight exceeding 50,000 but not more than 130,000.

Details regarding the polyimide precursor contained in the resin composition are as described above. This resin composition may contain a solvent in addition to the polyimide precursor. Examples of solvents which may be used include those solvents mentioned above as the synthesis solvent in the method for producing the polyimide precursor.

As this resin composition, the mixture of the obtained polyimide precursor and the synthesis solvent obtained upon solution polymerization of the polyimide precursor may be simply used. The resin composition may also be obtained by removing excess synthesis solvent from the obtained mixture, or by adding an additional dilution solvent.

The resin fraction of this resin composition is preferably within a range from 5 to 50% by mass, and more preferably from 10 to 30% by mass. The resin fraction may be adjusted within this range to achieve a more favorable viscosity range as a coating material.

This resin composition can be used favorably as a resin composition for flexible printed circuit boards.

The viscosity of the resin composition at 30° C. is preferably within a range from 1 to 10 Pa·s, and more preferably from 1 to 5 Pa·s.

In this description, the viscosity refers to a numerical value measured using a rotational B-type viscometer at 30° C. using a No. 3 rotor.

This resin composition may also contain additives if required. Examples of these additives include colorants such as pigments or dyes, inorganic fillers, organic fillers, and lubricants and the like. By including a low-dielectric constant filler in the resin composition, an even lower dielectric constant can be achieved for the resulting polyimide molded article. On the other hand, because the polyimide according to one embodiment itself has a low dielectric constant, from the viewpoint of flexibility, the resin composition can also be used favorably in applications in which no filler is included in the polyimide molded article. For example, the amount of filler relative to the total mass of the polyimide molded article may be not more than 10% by mass, not more than 5% by mass, or 1% by mass or less, or the polyimide molded article may contain essentially no filler.

### (Polyimide)

A polyimide according to one embodiment of the present disclosure is characterized as being a polyimide obtained using the polyimide precursor according to an embodiment described above.

A polyimide according to another embodiment contains a diamine-derived structural unit and a tetracarboxylic dianhydride-derived structural unit, contains a dimer diamine-derived structural unit in an amount of from 5 to 80 mol % relative to total units of the diamine-derived structural unit, and has a breaking elongation of at least 95%.

One preferred example is a polyimide used for a base film of a high-frequency flexible printed circuit board, wherein the polyimide contains a diamine-derived structural unit and a tetracarboxylic dianhydride-derived structural unit, contains a dimer diamine-derived structural unit in an amount of at least 5 mol % but not more than 80 mol % relative to total units of the diamine-derived structural unit, and has a breaking elongation of at least 95%.

Another preferred example is a polyimide used for a base film of a flexible printed circuit board, wherein the polyimide contains a diamine-derived structural unit and a tetracarboxylic dianhydride-derived structural unis, contains a dimer diamine-derived structural unit in an amount of at least 5 mol % but not more than 80 mol % relative to total units of the diamine-derived structural unit, has a breaking elongation of at least 95%, and has a glass transition temperature of at least 200° C.

Yet another preferred example is a polyimide which contains a diamine-derived structural unit and a tetracarboxylic dianhydride-derived structural unit, contains a dimer diamine-derived structural unit in an amount of at least 10 mol % but less than 50 mol % of relative to total units of the diamine-derived structural unit, has a breaking elongation of at least 95%, and has a glass transition temperature of at least 200° C.

These polyimides described above have a high breaking elongation, and exhibit a low dielectric constant and low dielectric loss tangent. By using these polyimides, polyimide molded articles having superior dielectric characteristics and breaking elongation can be provided.

The polyimide may contain a diamine-derived structural unit and a tetracarboxylic dianhydride-derived structural unit.

In the polyimide, the diamine-derived structural units may be the diamine-derived structural units that can be used in the polyimide precursor described above. In the polyimide, the tetracarboxylic dianhydride-derived structural units may be the tetracarboxylic dianhydride-derived structural units that can be used in the polyimide precursor described above.

The polyimide may contain either one type of diamine-derived structural unit, or a combination of two or more types of diamine-derived structural units, and may contain either one type of tetracarboxylic dianhydride-derived structural unit, or a combination of two or more types of tetracarboxylic dianhydride-derived structural units.

In the polyimide, the diamine-derived structural units may include a dimer diamine-derived structural unit. In the polyimide, the dimer diamine-derived structural unit may be the dimer diamine-derived structural unit that can be used in the polyimide precursor described above.

The polyimide may contain a dimer diamine-derived structural unit in an amount of from 5 to 80 mol % relative to the total units of the diamine-derived structural unit.

From the viewpoints of lowering the dielectric constant and the dielectric loss tangent for the polyimide, the proportion of the dimer diamine-derived unit, relative to total units of the diamine-derived structural unit, is preferably at least 5 mol %, more preferably at least 10 mol %, even more preferably at least 20 mol %, and still more preferably 25 mol % or greater.

From the viewpoints of preventing any deterioration in the heat resistance, tensile strength and tensile modulus of elasticity of the polyimide, the proportion of the dimer diamine-derived unit, relative to total units of the diamine-derived structural unit, is preferably not more than 80 mol %, more preferably 50 mol % or less than 50 mol %, even more preferably not more than 45 mol %, and still more preferably 40 mol % or less. From the viewpoint of obtaining superior heat resistance and a high tensile strength or high tensile modulus of elasticity, this proportion of the dimer diamine is preferably not more than 40 mol %, more preferably not more than 35 mol %, and even more preferably 30 mol % or less.

From the viewpoint of lowering the dielectric constant and the dielectric loss tangent while maintaining various other characteristics, for example, the proportion of the dimer diamine-derived unit, relative to total units of the diamine-derived structural unit, is preferably within a range from 5 to 80 mol %, and more preferably from 10 to 80 mol %. Further, the proportion is preferably within a range from 10 to 50 mol %, or at least 10 mol % but less than 50 mol %, and more preferably from 20 to 40 mol %, and may be within a range from 20 to 30 mol %.

The polyimide preferably has a breaking elongation of at least 95%.

From the viewpoint of obtaining molded articles having superior flexibility, the breaking elongation of the polyimide is preferably at least 95%, more preferably at least 100%, even more preferably at least 110%, still more preferably at least 120%, and still more preferably 150% or greater. By ensuring a breaking elongation within one of these ranges, the polyimide can be used favorably in molded articles requiring favorable bending stress, such as flexible printed circuit boards.

There are no particular limitations on the breaking elongation of the polyimide, but the breaking elongation may be not more than 500%, not more than 400%, or 350% or less.

For example, the breaking elongation of the polyimide is preferably within a range from 95 to 500%, and may be from 100 to 400%, or from 150 to 350%.

The polyimide preferably has a tensile strength within a range from 10 to 400 MPa.

From the viewpoint of the material strength, the tensile strength of the polyimide is preferably at least 10 MPa, more preferably at least 50 MPa, even more preferably at least 70 MPa, and still more preferably 80 MPa or greater.

The tensile strength of the polyimide is preferably not more than 400 MPa, more preferably not more than 300 MPa, and may be 200 MPa or less. By ensuring a tensile strength within one of these ranges, the stretching process during film production can be conducted appropriately, and by aligning the molecular chains, a film with particularly superior in-plane characteristics can be obtained.

The polyimide preferably has a tensile modulus of elasticity within a range from 0.1 to 5 GPa.

From the viewpoint of the material strength, the tensile modulus of elasticity of the polyimide is preferably at least 0.1 GPa, more preferably at least 0.3 GPa, and may be 0.5 GPa or greater. If the tensile modulus of elasticity is less than 0.1 GPa, then when semiconductor elements are mounted, a phenomenon may occur in which wiring circuits or semiconductor elements may sink into the polyimide molded article.

The tensile modulus of elasticity of the polyimide is preferably not more than 5 GPa, more preferably not more than 3 GPa, even more preferably not more than 2.0 GPa, and still more preferably 1.6 GPa or less. By ensuring a tensile modulus of elasticity within one of these ranges, problems during use in vehicle-mounted millimeter-wave radar modules such as peeling caused by repulsive forces or mounting faults such as wiring breakages, or the requirement for extra space due to an increase in the folding radius can be ameliorated.

In this disclosure, the tensile strength of a polyimide represents a value obtained by setting a test piece of the polyimide with a width of 10 mm, a length of 60 mm and a thickness of 25 μm in a tensile tester with a chuck separation of 20 mm, and pulling the test piece at a rate of 5 mm/minute at 25° C., with the maximum tensile stress imparted during the tension test being deemed the tensile strength. The breaking elongation is determined by testing under the same conditions, and represents the value obtained by dividing the amount of elongation of the test piece at breakage by the chuck separation of 20 mm. The tensile modulus of elasticity is also determined by testing under the same conditions, and represents the value obtained by determining the Young's modulus (MPa) from the slope of the elastic deformation region in the initial stage of stress increase. Other details regarding the conditions and calculation methods were in accordance with the International Standard ISO 527-1:2019. For the tensile tester, a device such as an Autograph AGS-100NG manufactured by Shimadzu Corporation may be used.

One example of the polyimide includes a dimer diamine-derived structural unit in an amount of 5 to 20 mol % relative to total units of the diamine-derived structural unit, and has a breaking elongation of at least 95%. The polyimide of this example has a dielectric constant of not more than 3.3 or a dielectric loss tangent of not more than 0.005, or is capable of satisfying both of these conditions.

Another example of the polyimide includes a dimer diamine-derived structural unit in an amount of from 10 to 20 mol % relative to total units of the diamine-derived structural unit, and has a breaking elongation of at least 95%, and preferably 100% or greater. The polyimide of this example has a dielectric constant of not more than 3.0 or a dielectric loss tangent of not more than 0.003, or is capable of satisfying both of these conditions.

Yet another example of the polyimide includes a dimer diamine-derived structural unit in an amount of at least 20 mol % and either 50 mol % or less than 50 mol % relative to total units of the diamine-derived structural unit, and has a breaking elongation of at least 95%, and preferably 150% or greater. The polyimide of this example has a dielectric constant of not more than 2.9 or a dielectric loss tangent of not more than 0.0015, or is capable of satisfying both of these conditions.

Yet another example of the polyimide includes a dimer diamine-derived structural unit in an amount of at least 20 mol % and either 30 mol % or less than 30 mol % relative to total units of the diamine-derived structural unit, and has a breaking elongation of at least 95%, and preferably 150% or greater. The polyimide of this example has a dielectric constant of not more than 2.9 or a dielectric loss tangent of not more than 0.0015, or is capable of satisfying both of these conditions.

Yet another example of the polyimide includes a dimer diamine-derived structural unit in an amount of from 20 mol % to 80 mol % relative to total units of the diamine-derived structural unit, and has a breaking elongation of at least 95%, and preferably 150% or greater. The polyimide of this example has a dielectric constant of not more than 2.9 or a dielectric loss tangent of not more than 0.0015, or is capable of satisfying both of these conditions.

Yet another example of the polyimide includes a dimer diamine-derived structural unit in an amount of from 30 mol % to 80 mol % relative to total units of the diamine-derived structural unit, and has a breaking elongation of at least 95%, preferably at least 150%, and more preferably 300% or greater. The polyimide of this example has a dielectric constant of not more than 2.7 or a dielectric loss tangent of not more than 0.0015, or is capable of satisfying both of these conditions.

Yet another example of the polyimide includes a dimer diamine-derived structural unit in an amount of from 50 mol % to 80 mol % relative to total units of the diamine-derived structural unit, and has a breaking elongation of at least 95%, preferably at least 150%, and more preferably 300% or greater. The polyimide of this example has a dielectric constant of not more than 2.7 or a dielectric loss tangent of not more than 0.0015, or is capable of satisfying both of these conditions.

From the viewpoint of the heat resistance, the polyimide has a glass transition temperature (Tg) that is preferably within a range from 200 to 500° C., and more preferably from 300 to 500° C. From the viewpoint of the heat resistance, the glass transition temperature of the polyimide is preferably at least 200° C., more preferably at least 250° C., even more preferably at least 300° C., and still more preferably 350° C. or higher.

In a polyimide in which the proportion of the dimer diamine-derived structural unit relative to total units of the diamine-derived structural unit is at least 5 mol % but less than 30 mol %, the glass transition temperature is preferably within a range from 300 to 500° C., more preferably from 350 to 500° C., and even more preferably from 380 to 500° C.

In a polyimide in which the proportion of the dimer diamine-derived structural unit relative to total units of the diamine-derived structural unit is at least 30 mol % but less than 50 mol %, the glass transition temperature is preferably within a range from 200 to 500° C., more preferably from 300 to 500° C., and even more preferably from 320 to 500° C.

In a polyimide in which the proportion of the dimer diamine-derived structural unit relative to total units of the diamine-derived structural unit is at least 50 mol % but not more than 80 mol %, the glass transition temperature is preferably within a range from 200 to 500° C., more preferably from 250 to 500° C. and even more preferably from 300 to 500° C.

In this disclosure, the glass transition temperature is measured using a thermomechanical analyzer, by preparing a test piece with a width of 4 mm, a length of 25 mm and a thickness of 25 μm, and then conducting measurement in accordance with the following procedure. First, using a chuck separation of 10 mm and a load of 10 g, the test piece is heated under the tensile mode in a nitrogen atmosphere from room temperature (20° C.) to 350° C. at a rate of 10° C./minute, and after holding at this temperature for 30 minutes, the test piece is subsequently cooled to 30° C. at a rate of 10° C./minute to remove residual stress. Subsequently, using a chuck separation of 10 mm, this test piece is measured by the tensile method in a nitrogen atmosphere by raising the temperature from 20° C. to 500° C. at a rate of 10° C./minute, with the temperature at the inflection point being deemed the glass transition temperature (° C.).

From the viewpoint of the heat resistance, the 5%-weight reduction temperature (T_{d}) of the polyimide is preferably within a range from 200 to 600° C., and more preferably from 300 to 500° C.

In this disclosure, Td5 is measured under an inert atmosphere by raising the temperature from 50° C. to 500° C. at a rate of temperature increase of 10° C./minute, and indicates the temperature at which the weight has reduced by 5% from the initial weight.

From the viewpoint of obtaining a polyimide molded article with superior insulation properties, the dielectric constant of the polyimide is preferably not more than 3.3, and more preferably 3.0 or less. Further the dielectric constant of the polyimide is preferably at least 2.0 but not more than 3.3, and more preferably at least 2.0 but not more than 3.0.

More specifically, the dielectric constant of the polyimide is preferably within a range from 2.00 to 3.30.

From the viewpoint of the insulation properties, the dielectric constant of the polyimide is preferably not more than 3.30, more preferably not more than 3.20, even more preferably not more than 3.00, still more preferably not more than 2.80, and may be 2.60 or less.

Although there are no particular limitations, from the viewpoints of preventing any deterioration in the heat resistance, tensile strength and tensile modulus of elasticity, the dielectric constant of the polyimide may typically be 2.00 or greater.

From the viewpoint of obtaining a polyimide molded article with little transmission loss, the dielectric loss tangent of the polyimide is preferably not more than 0.015, and more preferably 0.003 or less. The dielectric loss tangent of the polyimide is preferably at least 0.0001 but not more than 0.015, and more preferably at least 0.0005 but not more than 0.003.

More specifically, from the viewpoint of reducing transmission loss, the dielectric loss tangent of the polyimide is preferably not more than 0.0150, more preferably not more than 0.0100, and even more preferably 0.0050 or less. Moreover, in applications requiring superior insulation properties, the dielectric loss tangent of the polyimide is preferably not more than 0.0030, more preferably not more than 0.0025, and even more preferably 0.0015 or less.

Although there are no particular limitations, the dielectric loss tangent of the polyimide may typically be at least 0.0001, and may be 0.0005 or greater.

In this disclosure, the dielectric constant and the dielectric loss tangent of a polyimide can be determined from the electrostatic capacitance and the thickness of the test piece in accordance with the cavity resonator perturbation method. Specifically, using a test piece prepared by cutting the polyimide to dimensions of 60 mm×60 mm with a thickness of 25 μm, the dielectric constant and the dielectric loss tangent can be measured by the cavity resonator perturbation method (TE mode). The measurement conditions include a frequency of 10 GHz and a measurement temperature of 25° C.

A polyimide having the characteristics described above can be obtained using the polyimide precursor described above, but is not limited to polyimides obtained using this method. A polyimide having the type of breaking elongation described above can be obtained by subjecting a high-molecular weight polyimide precursor to a dehydration cyclization.

### (Molded Article and Flexible Printed Circuit Board)

A polyimide molded article according to one embodiment of the present disclosure is characterized as containing the polyimide according to one of the embodiments described above. A polyimide molded article according to another embodiment of the present disclosure is characterized as being formed using the resin composition according to an embodiment described above. The polyimide molded article may be a plate-like board, a coating film that is applied to a base material, or any of various shapes that can be formed using a mold.

Further, a flexible printed circuit board (FPC) according to one embodiment of the present disclosure is characterized as containing the polyimide according to an embodiment described above. A flexible printed circuit board according to another embodiment of the present disclosure is characterized as containing a polyimide obtained using the resin composition described above.

The polyimide obtained using the polyimide precursor or resin composition according to one of the above embodiments has a low dielectric constant and a low dielectric loss tangent, and therefore by using the polyimide in a flexible printed circuit board, the board having superior insulation properties can be provided. Further, the polyimide according to one embodiment has superior heat resistance and flexibility, and can therefore be used favorably in a flexible printed circuit board. This type of flexible printed circuit board exhibits excellent dielectric characteristics, heat resistance and breaking elongation, and is therefore useful for application to vehicle-mounted pressure sensors, angle sensors, flexible printed circuit boards for inverter wiring, and millimeter-wave radar boards for use in vehicle-mounted millimeter-wave radar. Moreover, this type of flexible printed circuit board can be used particularly favorably in high-frequency flexible printed circuit boards, specifically, as the high-frequency flexible printed circuit board for use in millimeter-wave radar, high-frequency antennas, and boards for high-speed transmission and the like.

One example of the flexible printed circuit board has a base film, wherein the base film contains the polyimide according to one embodiment described above. Another example of the flexible printed circuit board has a base film and a coating film layer formed on the base film, wherein at least the coating film layer contains the polyimide according to one embodiment described above.

Specifically, the flexible printed circuit board may include a base film. The base film may be a single layer or a laminate. In the case of a single-layer base film, the polyimide according to an embodiment described above can be used for the base film. In the case of a laminate base film, a resin layer of the polyimide according to an embodiment and another resin layer may be used, or two or more types of polyimides according to embodiments described above and having different compositions may be used for at least two layers of the base film. The other resin layer may be formed from polyethylene terephthalate, a liquid crystal polymer, a polyamideimide, or another polyimide besides the polyimide of the embodiments described above. Because the polyimide according to an embodiment has a high breaking elongation, a base film can also be provided from a single layer of the polyimide.

The flexible printed circuit board may be a single-sided flexible printed circuit board in which a conductive layer of copper foil or the like is formed on one surface of the base film, or may be a double-sided flexible printed circuit board in which conductive layers of copper foil or the like are formed on both surfaces of the base film.

The flexible printed circuit board may include a base film and a coating film layer. The coating film layer may be formed as a protective film following formation of a conductive layer of copper foil or the like on the base film. In this type of flexible printed circuit board, at least one of the base film and the coating film layer preferably contains the polyimide of one embodiment. The base film having a polyimide according to an embodiment is as described above. In those cases where the base film is formed using another resin, the coating film layer preferably contains the polyimide of an embodiment. The base film and the coating film layer may both contain a polyimide according to one of the above embodiments.

The molded article or flexible printed circuit board according to an embodiment of the present disclosure contains a polyimide, wherein the polyimide contains a diamine-derived structural unit and a tetracarboxylic dianhydride-derived structural unit, contains a dimer diamine-derived structural unit in an amount of from 5 to 80 mol % relative to total units of the diamine-derived structural units, and has a breaking elongation of at least 95%. Details regarding the polyimide are as described above. This molded article or flexible printed circuit board may be formed using a resin composition containing the polyimide precursor according to an embodiment described above, but is not limited to articles formed using this method.

One example of a method for producing a plate-like or coating film-like polyimide molded article may include applying a resin composition containing the polyimide precursor and a solvent, and then conducting heating. The polyimide precursor, the solvent and the resin composition may be as described above. By using this method, a polyimide molded article having excellent insulation properties, heat resistance, strength, hydrolysis resistance, and chemical resistance and the like can be provided.

A coating film-like polyimide molded article can be obtained by applying a resin composition to a substrate and then conducting heating. The substrate may be a rigid substrate such as a glass or metal, or may be a flexible substrate such as a resin. The polyimide of an embodiment may be used as a material for the flexible substrate.

A plate-like polyimide molded article can be obtained by applying the resin composition to a temporary fixing substrate, conducting heating to form a polyimide resin layer, and then detaching the polyimide resin layer from the temporary fixing substrate. This type of plate-like polyimide molded article can be used as a flexible printed circuit board.

A polyimide molded article can also be molded into any of various shapes by using the resin composition to fill a mold and then conducting heating.

The method used for applying the resin composition to a substrate may be a method in which the resin composition is applied to the surface of the substrate, or a method in which the substrate is dipped in the resin composition. Specific examples include brush application, dip coating, spin coating, cast coating, blade coating and spray coating.

The resin composition applied to the substrate can be cured by heating to form the polyimide molded article.

The heating temperature is preferably within a range from 260 to 520° C. By ensuring the heating temperature is at least as high as this lower limit, the solvent can be removed from the molded article so that no residual solvent remains, the curing of the molded article can be accelerated, and the characteristics can be further improved. Further, if a polar solvent is retained in the molded article, there is a possibility that resin components may dissolve or swell due to the presence of the polar solvent, causing a deterioration in the characteristics of the molded article. Provided the heating temperature is no higher than the above upper limit, degradation of the molded article due to the heat can be prevented.

The heating time is preferably within a range from one minute to one hour. A time within this range ensures no residual solvent is retained in the molded article. Further, by ensuring that the heating time is not too long, degradation of the molded article due to the heat can be prevented.

In this description, numerical ranges indicated using the expression “a to b” indicate a range that includes the numerical values before and after the “to” as the minimum value and maximum value respectively. In the case of numerical ranges listed in a stepwise manner in this description, the upper limit value or lower limit value from the numerical range of any particular step may be arbitrarily combined with the upper limit value or lower limit value from the numerical range of another step. Unless specifically stated otherwise, for all materials exemplified in this description, a single material may be used alone, or a combination of two or more materials may be used. In this description, unless specifically stated otherwise, the amount of each component in a composition, in the case where a plurality of substances corresponding with any particular component exist in the composition, means the total amount of the plurality of substances that exist in the composition. The term “step” refers to not only independent steps, but also includes steps that achieve an intended action, even if the step cannot be clearly differentiated from another step.

Some embodiments are further described below as examples.

One embodiment is a polyimide precursor obtained by reacting a diamine and a tetracarboxylic dianhydride, wherein the polyimide precursor contains from 5 to 80 mol % of a dimer diamine relative to the diamine component contained in the polyimide precursor, and has a weight average molecular weight within a range from 15,000 to 130,000. Also, a polyimide obtained by curing this polyimide precursor, a resin composition containing this polyimide precursor, a polyimide molded article formed using this resin composition, and a flexible board having a polyimide formed using this resin composition.

Another embodiment is a polyimide containing a diamine-derive structural unit and a tetracarboxylic dianhydride-derived structural unit, wherein the polyimide contains a dimer diamine-derived structural unit in an amount of from 5 to 80 mol % relative to total units of the diamine-derived structural unit, and has a breaking elongation of at least 95%. Also, a flexible board having this polyimide.

### EXAMPLES

The present invention is described below in further detail using a series of examples, but the present invention is not limited to these examples.

The formulations and evaluation results for the examples are shown in Table 1.

### Example 1

First, 79.9 g (0.15 mol) of a dimer diamine (brand name: PRIAMIONE 1075, manufactured by Croda Japan K.K., hereinafter abbreviated as “DDA”) and 29.9 g (0.15 mol) of 4,4′-diaminodiphenyl ether (hereinafter abbreviated as “ODA”) as diamine components were dissolved in 700.0 g of N-methyl-2-pyrrolidone, and 63.9 g (0.29 mol) of pyromellitic dianhydride (hereinafter abbreviated as “PMDA”) was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 2

First, 67.8 g (0.13 mol) of DDA and 38.1 g (0.19 mol) of ODA as diamine components were dissolved in 700.0 g of N-methyl-2-pyrrolidone, and 67.7 g (0.31 mol) of PMDA was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 3

First, 46.6 g (0.087 mol) of DDA and 52.4 g (0.26 mol) of ODA as diamine components were dissolved in 700.0 g of N-methyl-2-pyrrolidone, and 74.5 g (0.34 mol) of PMDA was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 4

First, 20.7 g (0.039 mol) of DDA and 69.8 g (0.35 mol) of ODA as diamine components were dissolved in 700.0 g of N-methyl-2-pyrrolidone, and 82.8 g (0.38 mol) of PMDA was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 5

First, 10.8 g (0.020 mol) of DDA and 76.5 g (0.38 mol) of ODA as diamine components were dissolved in 700.0 g of N-methyl-2-pyrrolidone, and 86.0 g (0.40 mol) of PMDA was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 6

First, 83.8 g (0.42 mol) of ODA as a diamine component was dissolved in 700.0 g of N-methyl-2-pyrrolidone, and 89.4 g (0.41 mol) of PMDA was then added as an acid anhydride component and reacted. This reaction was conducted at not more than 50° C. for at least 3 hours under constant stirring. After stirring for at least 3 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 7

First, 40.5 g (0.076 mol) of DDA and 45.5 g (0.23 mol) of ODA as diamine components were dissolved in 700.0 g of N-methyl-2-pyrrolidone, and 87.3 g (0.30 mol) of 3,3′,4,4′-biphenyltetracarboxylic dianhydride (hereinafter abbreviated as “s-BPDA”) was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 8

First, 35.5 g (0.066 mol) of DDA and 81.7 g (0.20 mol) of 2,2-bis[4-(4-aminophenoxy)phenyl]propane (hereinafter abbreviated as “BAPP”) as diamine components were dissolved in 700.0 g of N-methyl-2-pyrrolidone, and 56.7 g (0.26 mol) of PMDA was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### Example 9

First, 31.8 g (0.060 mol) of DDA and 73.2 g (0.18 mol) of BAPP as diamine components were dissolved in 700.0 g of N-methyl-2-pyrrolidone, and 68.6 g (0.23 mol) of s-BPDA was then added as an acid anhydride component and reacted. This reaction was conducted at not more than 50° C. for at least 8 hours under constant stirring. After stirring for at least 8 hours, the reaction product was sampled, the weight average molecular weight and number average molecular weight were measured, and the reaction was halted once the reaction was deemed to have progressed sufficiently. Upon halting the reaction, a resin composition was obtained which had the resin fraction concentration shown in the table and contained a polyimide precursor having a structural unit derived from the dimer diamine. Visual inspection of the external appearance of this resin composition revealed a uniform and transparent composition.

### (Weight Average Molecular Weight and Number Average Molecular Weight of Resin Compositions)

The resin composition containing a polyimide precursor from each example was measured using the procedure described below.

The weight average molecular weight (Mw) and number average molecular weight (Mn) values were measured by gel permeation chromatography (GPC), and represent values referenced against a calibration curve of standard polystyrenes. The calibration curve was approximated as a cubic equation using a 5-sample set of standard polystyrenes (TSK Standard POLYSTYRENE [brand name, manufactured by Tosoh Corporation]). The GPC conditions are shown below.
GPC apparatus: high-speed GPC apparatus HLC-8320GPC (brand name, manufactured by Tosoh Corporation)
Detector: ultraviolet absorption detector UV-8320 (brand name, manufactured by Tosoh Corporation)
Columns: Gelpack GL-S300MDT-5 (total: 2 columns) (brand name, manufactured by Show Denko Materials Co., Ltd.).
Eluent: THF/DMF=1/1 (volumetric ratio)+LiBr (0.06 mol/L)+H₃PO₄ (0.06 mol/L)
Flow rate: 1 ml/minute
Column size: 8 mm I.D.×300 mm
Sample concentration: 5 mg/l mL
Injection volume: 5 μL
Measurement temperature: 40° C.

### (Film Production)

Using the resin composition containing a polyimide precursor from each example, a film was produced using the procedure described below.

The surface of a commercially available glass substrate was degreased with acetone, a film applicator with a film thickness adjustment function was used to apply the resin composition in an amount sufficient to achieve a film thickness following curing of 25 μm, and the resin composition was then subjected to preliminary drying at 80° C. for 60 minutes using a hot plate. Next, an inert gas oven was used to bake the substrate and film at 150° C. for 30 minutes, at 200° C. for 30 minutes, at 250° C. for 30 minutes, and then at 350° C. for one hour, thus obtaining a polyimide cured film. The cured film was then dipped in hot water for about 15 minutes and detached from the glass substrate.

### (Dielectric Constant and Dielectric Loss Tangent of Films)

The cured film from each example obtained in the manner described above was cut to a size of 60 mm×60 mm, and following a drying treatment at 120° C. for 15 minutes, the dielectric characteristics (the dielectric constant Dk and the dielectric loss tangent Df) were measured using the cavity resonator method (TE mode). The apparatus used was an MS46122B apparatus manufactured by Anritsu Corporation. The measurement conditions included a frequency of 10 GHz and a measurement temperature of 25° C.

(Tensile Strength, Tensile Modulus of Elasticity, and Breaking elongation of Films)

The tensile strength, tensile modulus of elasticity and breaking elongation of the film from each example were measured using the procedure described below.

The cured film obtained above was cut to a size with a width of 10 mm and a length of 60 mm to form a test piece. This test piece was subjected to tensile testing under the measurement conditions described below, and the maximum tensile stress imparted during the tension test being deemed the tensile strength. Further, the breaking elongation was calculated by dividing the amount of elongation of the film at breakage by the chuck separation of 20 mm. The Young's modulus (MPa) was calculated from the slope of the elastic deformation region in the initial stage of stress increase, and this value was deemed the tensile modulus of elasticity. Other details regarding the conditions and calculation methods were in accordance with the International Standard ISO 527-1:2019.
Apparatus name: Autograph AGS-100NG (brand name) manufactured by Shimadzu Corporation
Test speed: 5 mm/min
Chuck separation: 20 mm
Test piece size: width 10 mm, length 60 mm
Temperature setting: room temperature (25° C.)

### (Glass Transition Temperature of Films)

The cured film from each example was cut to a width of 4 mm and a length of 25 mm to prepare a test piece, and this test piece was measured using the procedure described below. First, using a chuck separation of 10 mm and a load of 10 g, the test piece was heated under the tensile mode in a nitrogen atmosphere from room temperature (20° C.) to 350° C. at a rate of 10° C./minute, and after holding at this temperature for 30 minutes, the test piece was subsequently cooled to 30° C. at a rate of 10° C./minute to remove residual stress. Subsequently, using a thermomechanical analyzer (brand name: TMA710, manufactured by Hitachi High-Tech Science Corporation) with a chuck separation of 10 mm, this test piece was measured by the tensile method in a nitrogen atmosphere by raising the temperature from 20° C. to 500° C. at a rate of 10° C./minute, with the temperature at the inflection point being deemed the glass transition temperature (° C.).

TABLE 1

| | | Example 1 | Example 2 | Example 3 | Example 4 | Example 5 | Example 6 |
|---|---|---|---|---|---|---|---|
| Composition | PMDA | 0.29 | 0.31 | 0.34 | 0.38 | 0.40 | 0.41 |
| (mol) | s-BPDA | — | — | — | — | — | — |
| | ODA | 0.15 | 0.19 | 0.26 | 0.35 | 0.38 | 0.42 |
| | BAPP | — | — | — | — | — | — |
| | DDA | 0.15 | 0.13 | 0.087 | 0.039 | 0.020 | 0 |
| | DDA within diamine | 50 | 40 | 25 | 10 | 5 | 0 |
| | component (mol %) | | | | | | |
| Resin | Weight average | 69,800 | 80,100 | 78,400 | 86,500 | 82,400 | 81,600 |
| composition | molecular weight | | | | | | |
| characteristics | Number average | 36,700 | 47,000 | 48,000 | 51,200 | 50,100 | 50,400 |
| | molecular weight | | | | | | |
| | Resin fraction | 18.3 | 18.4 | 18.2 | 18.4 | 18.5 | 17.3 |
| | concentration | | | | | | |
| | (% by mass) | | | | | | |
| Film | Dielectric constant | 2.66 | 2.73 | 2.86 | 2.99 | 3.15 | 3.43 |
| characteristics | Dk (10 GHz) | | | | | | |
| | Dielectric loss tangent | 0.0014 | 0.0014 | 0.0014 | 0.0030 | 0.0046 | 0.0164 |
| | Df (10 GHz) | | | | | | |
| | Tensile strength (MPa) | 62.5 | 75.8 | 82.7 | 137.1 | 158.2 | 204.5 |
| | Tensile modulus of | 0.3 | 0.8 | 1.3 | 1.6 | 1.7 | 2.1 |
| | elasticity (GPa) | | | | | | |
| | Breaking | 312 | 252 | 165 | 107 | 97 | 81 |
| | elongation (%) | | | | | | |
| | Glass transition | 329 | 355 | 396 | 399 | 404 | 405 |
| | temperature (° C.) | | | | | | |

TABLE 2

| | | Example | Example | Example |
|---|---|---|---|---|
| | | 7 | 8 | 9 |
| Composi- | PMDA | — | 0.26 | — |
| tion | s-BPDA | 0.30 | — | 0.23 |
| (mol) | ODA | 0.23 | — | — |
| | BAPP | — | 0.20 | 0.18 |
| | DDA | 0.076 | 0.066 | 0.060 |
| | DDA within | 25 | 25 | 25 |
| | diamine | | | |
| | component | | | |
| | (mol %) | | | |
| Resin | Weight average | 84,400 | 85,800 | 86,100 |
| composi- | molecular weight | | | |
| tion | Number average | 53,000 | 53,100 | 54,900 |
| charac- | molecular weight | | | |
| teristics | Resin fraction | 18.3 | 18.1 | 18.4 |
| | concentration | | | |
| | (% by mass) | | | |
| Film | Dielectric | 2.99 | 2.84 | 2.77 |
| charac- | constant Dk | | | |
| teristics | (10 GHz) | | | |
| | Dielectric loss | 0.0009 | 0.0014 | 0.0042 |
| | tangent Df | | | |
| | (10 GHz) | | | |
| | Tensile strength | 210.3 | 66.5 | 36.4 |
| | (MPa) | | | |
| | Tensile modulus | 6.2 | 1.1 | 1.8 |
| | of elasticity (GPa) | | | |
| | Breaking | 122 | 127 | 108 |
| | elongation (%) | | | |
| | Glass transition | 382 | 380 | 211 |
| | temperature (° C.) | | | |

As shown in Table 1 and Table 2, in Examples 1 to 5 and 7 to 9, by using a polyimide precursor containing a dimer diamine (DDA), films of low dielectric constant and low dielectric loss tangent were able to be obtained. It is evident that the polyimide films of Examples 1 to 5 and 7 to 9 had a low dielectric constant and low dielectric loss tangent, while also exhibiting superior breaking elongation. It is also evident that because the polyimide precursors contained in the resin compositions of Examples 1 to 5 and 7 to 9 each had a large weight average molecular weight, molded articles having a high breaking elongation were able to be produced. It is clear that the polyimide films of Examples 1 to 5 and 7 to 9 are, for example, suitable as films for use as base films in flexible printed circuit boards.

Example 6 represents a film produced using a polyimide precursor that contained no dimer diamine, and the dielectric constant and dielectric loss tangent were higher, indicating satisfactory dielectric characteristics could not be achieved, and the breaking elongation was also lower.

1. A polyimide precursor which contains a diamine-derived structural unit and a tetracarboxylic dianhydride-derived structural unit,
wherein (i) the polyimide precursor contains a dimer diamine-derived structural unit in an amount of at least 10 mol % but not more than 80 mol % relative to total units of the diamine-derived structural unit, has a weight average molecular weight of at least 15,000 but not more than 130,000, and is used for a base film of a flexible printed circuit board; or (ii) the polyimide precursor contains a dimer diamine-derived structural unit in an amount of at least 10 mol % but less than 50 mol % relative to total units of the diamine-derived structural unit, and has a weight average molecular weight exceeding 50.000 but not more than 130,000.

2. The polyimide precursor according to claim 1, wherein (ii) the polyimide precursor contains a dimer diamine-derived structural unit in an amount of at least 10 mol % but less than 50 mol % relative to total units of the diamine-derived structural unit, and has a weight average molecular weight exceeding 50,000 but not more than 130,000.

3. A resin composition comprising the polyimide precursor according to claim 1.

4. A polyimide obtained using the polyimide precursor according to claim 1.

5. A polyimide which contains a diamine-derived structural unit and a tetracarboxylic dianhydride-derived structural unit,
wherein (a) the polyimide contains a dimer diamine-derived structural unit in an amount of at least 5 mol % but not more than 80 mol % relative to total units of the diamine-derived structural unit, has a breaking elongation of at least 95%, and is used for a base film of a high-frequency flexible printed circuit board; (b) the polyimide contains a dimer diamine-derived structural unit in an amount of at least 5 mol % but not more than 80 mol % relative to total units of the diamine-derived structural unit, has a breaking elongation of at least 95% and a glass transition temperature of at least 200° C. and is used for a base film of a flexible printed circuit board; or (c) the polyimide contains a dimer diamine-derived structural unit in an amount of at least 10 mol % but less than 50 mol % relative to total units of the diamine-derived structural unit, and has a breaking elongation of at least 95% and a glass transition temperature of at least 200° C.

6. The polyimide according to claim 5, wherein (b) the polyimide contains a dimer diamine-derived structural unit in an amount of at least 5 mol % but not more than 80 mol % relative to total units of the diamine-derived structural unit, has a breaking elongation of at least 95% and a glass transition temperature of at least 200° C., and is used for a base film of a flexible printed circuit board.

7. The polyimide according to claim 5, wherein (c) the polyimide contains a dimer diamine-derived structural unit in an amount of at least 10 mol % but less than 50 mol % relative to total units of the diamine-derived structural unit, and has a breaking elongation of at least 95% and a glass transition temperature of at least 200° C.

8. The polyimide according to claim 4, wherein a dielectric constant Dk (10 GHz) is not more than 3.3.

9. The polyimide according to claim 4, wherein a dielectric loss tangent Df (10 GHz) is not more than 0.003.

10. The polyimide according to claim 4, wherein a glass transition temperature is at least 300° C.

11. A polyimide molded article comprising the polyimide according to claim 4.

12. A flexible printed circuit board comprising the polyimide according to claim 4.

13. A flexible printed circuit board comprising a base film obtained using the polyimide according to claim 4.

14. A flexible printed circuit board comprising a base film and a coating film layer formed on the base film, wherein at least the coating film layer is obtained using the polyimide according to claim 4.

15. The flexible printed circuit board according to claim 12, which is used for a millimeter-wave radar, a high-frequency antenna or a substrate for high-speed transmission.

16. The polyimide precursor according to claim 1, wherein (i) the polyimide precursor contains a dimer diamine-derived structural unit in an amount of at least 10 mol % but not more than 80 mol % relative to the total units of the diamine-derived structural unit, has a weight average molecular weight of at least 15,000 but not more than 130,000, and is used for a base film of a flexible printed circuit board.

17. The polyimide according to claim 5, wherein (a) the polyimide contains a dimer diamine-derived structural unit in an amount of at least 5 mol % but not more than 80 mol % relative to total units of the diamine-derived structural unit, has a breaking elongation of at least 95%, and is used for a base film of a high-frequency flexible printed circuit board.

18. A polyimide molded article comprising the polyimide according to claim 5.

19. A flexible printed circuit board comprising the polyimide according to claim 5.

20. A flexible printed circuit board comprising a base film obtained using the polyimide according to claim 5.
